(19) United States
(12) Patent Application Publication
(10) Pub. No.: US 2019/0379329 A1
(43) Pub. Date: Dec. 12, 2019

(54) DRIVER FOR RADIO FREQUENCY (RF) SWITCHED-CAPACITOR POWER AMPLIFIER (SCPA)

(71) Applicant: QUALCOMM Incorporated, San Diego, CA (US)

(72) Inventor: Chi-Fung KWOK, London (GB)

(21) Appl. No.: 16/006,661

(22) Filed: Jun. 12, 2018

(51) Int. Cl. H03F 1/02; H03F 3/45; H03F 3/24; H03F 3/193; H03K 19/0175

(52) U.S. Cl. CPC H03F 1/0205; H03F 3/45179; H03F 3/245; H03F 3/193; H04B 1/40; H03F 2200/451; H03F 2200/294; H03F 2200/165; H03F 2200/171; H03K 19/017509

(57) ABSTRACT

A signal processing circuit is described. The signal processing circuit includes a power amplifier. The power amplifier is composed of at least a p-type metal oxide semiconductor (PMOS) transistor and an n-type metal oxide semiconductor (NMOS) transistor. The signal processing circuit also includes a driver circuit. The driver circuit includes a first linear voltage regulator having an output coupled to a power supply input of a second linear voltage regulator. The first linear voltage regulator and the second linear voltage regulator are each coupled to the power amplifier.

### BACKGROUND

### Field

The present disclosure relates generally to wireless communications systems and, more specifically, to an efficient driver for a high power radio frequency (RF) switched-capacitor power amplifier (SCPA).

### Background

A wireless device (e.g., a cellular phone or a smartphone) in a wireless communications system may include a radio frequency (RF) transceiver for transmitting and receiving data for two-way communication. A mobile RF transceiver may include a transmit section for transmitting data and a receive section for receiving data. For transmitting data, the transmit section may modulate an RF carrier signal with data to obtain a modulated RF signal, amplify the modulated RF signal to obtain an amplified RF signal having the proper output power level and transmit the amplified RF signal via an antenna to a base station. For receiving data, the receive section may obtain a received RF signal via the antenna. The receive section may amplify and process the received RF signal to recover data sent by a base station.

In a mobile RF transceiver, a communication signal is amplified and transmitted by a transmit section. The transmit section may include one or more circuits for amplifying and transmitting the communication signal. The amplifier circuits may include one or more amplifier stages that may have one or more driver stages and one or more power amplifier stages. A power amplifier may include one or more stages including, for example, driver stages, power amplifier stages, or other components, that can be configured to amplify a communication signal on one or more frequencies, in one or more frequency bands, and at one or more power levels.

Conventional power amplifiers generally operate at a saturated power level, which results in less efficient operation. In addition, supporting a high output power level often involves implementing these conventional power amplifier using double-oxide (DO) devices (e.g., a double gate oxide thickness or second gate oxide thickness). While using double-oxide devices enables support for high power level operation, double-oxide devices are inherently much slower than single-oxide (SO) devices (e.g., a single gate oxide thickness or first gate oxide layer thickness less than the second gate oxide layer thickness). Furthermore, using double-oxide devices in a power amplifier lowers the power amplifier's efficiency because double-oxide devices are more resistive than conventional single-oxide devices. Double-oxide devices also present larger load capacitances to the driver, increasing the driver power (=C*V²*frequency), where C is the load capacitance, and V is the voltage across the driver.

### SUMMARY

A signal processing circuit is described. The signal processing circuit includes a power amplifier. The power amplifier is composed of at least a p-type metal oxide semiconductor (PMOS) transistor and an n-type metal oxide semiconductor (NMOS) transistor. The signal processing circuit also includes a driver circuit. The driver circuit includes a first linear voltage regulator having an output coupled to a power supply input of a second linear voltage regulator. The first linear voltage regulator and the second linear voltage regulator are each coupled to the power amplifier.

A method of sharing charge in a signal processing circuit is described. The method includes discharging a current from a gate of a p-type metal oxide semiconductor (PMOS) switching device of a switched-capacitor power amplifier through a driver network coupled to the switched-capacitor power amplifier. The method also includes charging a gate of an n-type metal oxide semiconductor (NMOS) switching device of the switched-capacitor power amplifier using the current discharged from the PMOS switching device.

A signal processing circuit is described. The signal processing circuit includes a differential digital power amplifier. The differential digital power amplifier is composed of at least a p-type metal oxide semiconductor (PMOS) transistor and an n-type metal oxide semiconductor (NMOS) transistor. The signal processing circuit also includes means for conducting charge from a gate of the PMOS transistor through a linear voltage regulator to a gate of the NMOS transistor of the differential digital power amplifier.

This has outlined, rather broadly, the features and technical advantages of the present disclosure in order that the detailed description that follows may be better understood. Additional features and advantages of the present disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 shows a wireless device communicating with a wireless system.

FIG. 2 shows a block diagram of the wireless device in FIG. 1.

FIG. 3 is a schematic diagram illustrating a radio frequency (RF) front-end (RFFE) module, including a driver circuit for a digital power amplifier, according to aspects of the present disclosure.

FIG. 4A is a schematic diagram illustrating a portion of the RFFE module of FIG. 3, for enabling charge sharing through a driver circuit for a digital power amplifier, according to aspects of the present disclosure.

FIG. 4B is a schematic diagram illustrating a portion of the RFFE module of FIG. 3, and cascode devices of a digital power amplifier having a driver circuit configured to enable charge sharing, according to aspects of the present disclosure.

FIG. 5 is a schematic diagram illustrating a portion of the RFFE module of FIG. 3, for configuring charge sharing through a driver circuit for a digital power amplifier, according to aspects of the present disclosure.

FIG. 6 is a schematic diagram illustrating an RF front-end (RFFE) module, including an efficient driver for a high power radio frequency (RF) digital power amplifier, according to aspects of the present disclosure.

FIG. 7 is a flow diagram illustrating a method of sharing charge in a signal processing circuit, in accordance with aspects of the present disclosure.

FIG. 8 is a block diagram showing an exemplary wireless communications system in which an aspect of the present disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Designing mobile radio frequency (RF) chips (e.g., mobile RF transceivers) becomes complex at deep sub-micron process nodes due to cost and power consumption considerations. A wireless device (e.g., a cellular phone or a smartphone) in a wireless communications system may include a mobile RF transceiver for transmitting and receiving data for two-way communication. A mobile RF transceiver may include a transmit section for transmitting data and a receive section for receiving data. For transmitting data, the transmit section modulates an RF carrier signal with data to obtain a modulated RF signal. The transmit section amplifies the modulated RF signal to obtain an amplified RF signal having the proper output power level and transmits the amplified RF signal via an antenna to a base station. The transmit section may include one or more circuits for amplifying and transmitting the communication signal. The amplifier circuits may include one or more amplifier stages that may have one or more driver stages and one or more power amplifier stages. A power amplifier may include one or more stages including, for example, driver stages, amplifier stages, or other components. The stages of the power amplifier are configured to amplify the communication signal on one or more frequencies, in one or more frequency bands, and at one or more power levels for supporting a mobile RF transceiver.

A switched-capacitor (SC) power amplifier (SCPA) is a type of digital power amplifier that possesses advantages over conventional power amplifiers. Advantages of SCPA digital power amplifiers include highly linear amplitude modulation (AM) and improved efficiency relative to conventional power amplifiers. The improved efficiency of SCPA digital power amplifiers is achieved by operating at a back-off power level from a saturated power level used to operate conventional power amplifiers. This feature of SCPA digital power amplifiers makes them an attractive candidate for fifth-generation (5G) communications systems. SCPA digital power amplifiers are also attractive candidates for improving efficiency in 5G communications systems that exhibit a large peak-average-power-ratio (PAPR), such as WiFi and LTE systems.

Conversely, conventional power amplifiers generally operate at a saturated power level for supporting a high output power level, which results in less efficient operation. In addition, supporting a high output power level often involves implementing these conventional power amplifiers using double-oxide (DO) devices (e.g., a double-gate oxide thickness). While using double-oxide devices enables support for high power level operation, double-oxide devices are inherently much slower than single-oxide (SO) devices. Furthermore, using double-oxide devices in a power amplifier lowers the power amplifier's efficiency because double-oxide devices are more resistive than conventional single-oxide devices. Double-oxide devices also present larger load capacitances to the driver, increasing the driver power.

An SCPA digital power amplifier may be implemented using an inverter/buffer type of driver from a power amplifier supply. If the power amplifier is configured to generate high output power, the power amplifier devices are large and a driver current will impact the overall power amplifier driver and efficiency. The SCPA digital power amplifier may specify a pair of n-type metal oxide semiconductor (NMOS) and p-type metal oxide semiconductor (PMOS) drivers, which may double the driver current when implemented as double-oxide devices. The proposed architecture addresses these issues by using single-oxide devices in at least a driver stage of a digital power amplifier. Using single-oxide devices in the digital power amplifier may achieve higher power amplifier efficiency while using less driver current.

Aspects of the present disclosure include a driver network coupled to a power amplifier of a signal processing circuit. In aspects of the present disclosure, the driver network is configured to receive a first data signal having a first voltage range and to convert the first data signal to a second data signal having a second voltage range larger than the first voltage range. In this aspect of the present disclosure, current from a p-type metal oxide semiconductor (PMOS) switching device of a switched-capacitor power amplifier is discharged through the driver network coupled to the switched-capacitor power amplifier. In addition, an n-type metal oxide semiconductor (NMOS) switching device of the switched-capacitor power amplifier is charged using the current discharged from the PMOS switching device. This charge sharing using the driver network between the PMOS and NMOS switching devices of the signal processing device reduces driver current consumption.

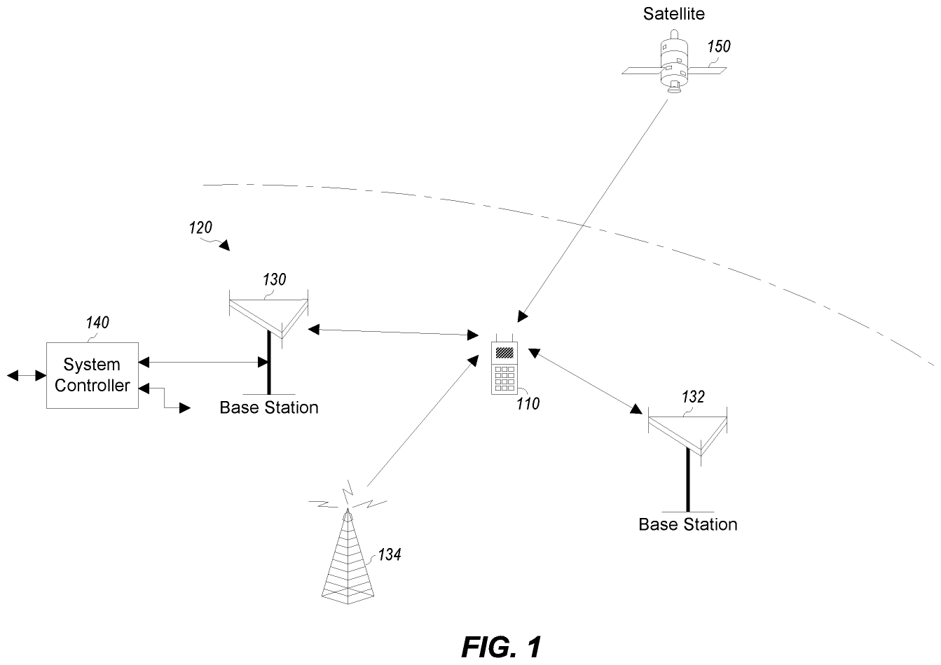

FIG. 1 shows a wireless device 110 communicating with a wireless communications system 120, including a switched-capacitor power amplifier (SCPA), according to aspects of the present disclosure. The wireless communications system 120 may be a 5G system, a long term evolution (LTE) system, a code division multiple access (CDMA) system, a global system for mobile communications (GSM) system, a wireless local area network (WLAN) system, or some other wireless system. A CDMA system may implement wideband CDMA (WCDMA), time division synchronous CDMA (TD-SCDMA), CDMA2000, or some other version of CDMA. For simplicity, FIG. 1 shows the wireless communications system 120 including two base stations 130 and 132 and one system controller 140. In general, a wireless system may include any number of base stations and any number of network entities.

A wireless device 110 may also be referred to as a user equipment (UE), a mobile station, a terminal, an access terminal, a subscriber unit, a station, etc. The wireless device 110 may be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. For example, the wireless device 110 may support Bluetooth Low Energy (BLE)/BT (Bluetooth) with a low energy/high efficiency power amplifier having a small form factor of a low cost.

The wireless device 110 may be capable of communicating with the wireless communications system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communications such as 5G, LTE, CDMA2000, WCDMA, TD-SCDMA, GSM, 802.11, BLE/BT, etc. The wireless device 110 may also support carrier aggregation, which is operation on multiple carriers.

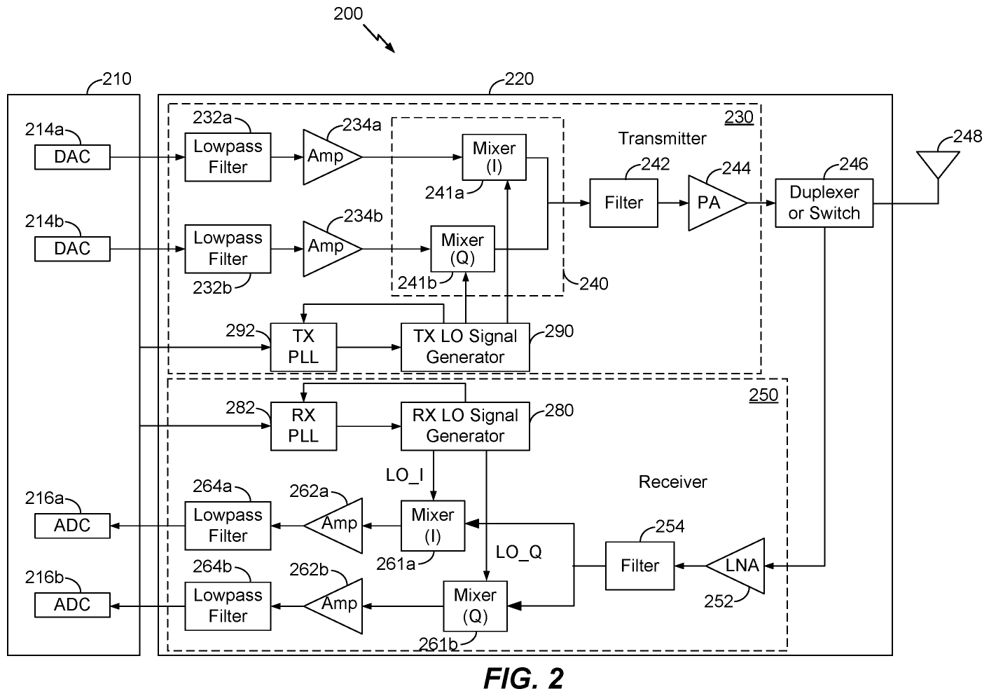

FIG. 2 shows a block diagram of an exemplary design of a wireless device 200, such as the wireless device 110 shown in FIG. 1, including a switched-capacitor power amplifier (SCPA), according to aspects of the present disclosure. FIG. 2 shows an example of a mobile RF transceiver 220, which may be a wireless transceiver (WTR). In general, the conditioning of the signals in a transmitter 230 and a receiver 250 may be performed by one or more stages of amplifier(s), filter(s), upconverters, downconverters, and the like. These circuit blocks may be arranged differently from the configuration shown in FIG. 1. Furthermore, other circuit blocks not shown in FIG. 2 may also be used to condition the signals in the transmitter 230 and receiver 250. Unless otherwise noted, any signal in FIG. 2, or any other figure in the drawings, may be either single-ended or differential. Some circuit blocks in FIG. 2 may also be omitted.

In the example shown in FIG. 2, the wireless device 200 generally includes the mobile RF transceiver 220 and a data processor 210. The data processor 210 may include a memory (not shown) to store data and program codes, and may generally include analog and digital processing elements. The mobile RF transceiver 220 may include the transmitter 230 and receiver 250 that support bi-directional communication. In general, the wireless device 200 may include any number of transmitters and/or receivers for any number of communications systems and frequency bands. All or a portion of the mobile RF transceiver 220 may be implemented on one or more analog integrated circuits (ICs), radio frequency (RF) integrated circuits (RFICs), mixed-signal ICs, and the like.

A transmitter or a receiver may be implemented with a super-heterodyne architecture or a direct-conversion architecture. In the super-heterodyne architecture, a signal is frequency-converted between radio frequency and baseband in multiple stages, for example, from radio frequency to an intermediate frequency (IF) in one stage, and then, from intermediate frequency to baseband in another stage for a receiver. In the direct-conversion architecture, a signal is frequency converted between radio frequency and baseband in one stage. The super-heterodyne and direct-conversion architectures may use different circuit blocks and/or have different requirements. In the example shown in FIG. 2, the transmitter 230 and the receiver 250 are implemented with the direct-conversion architecture.

In a transmit path, the data processor 210 processes data to be transmitted. The data processor 210 also provides in-phase (I) and quadrature (Q) analog output signals to the transmitter 230 in the transmit path. In an exemplary aspect, the data processor 210 includes digital-to-analog-converters (DACs) 214a and 214b for converting digital signals generated by the data processor 210 into the in-phase (I) and quadrature (Q) analog output signals (e.g., I and Q output currents) for further processing.

Within the transmitter 230, lowpass filters 232a and 232b filter the in-phase (I) and quadrature (Q) analog transmit signals, respectively, to remove undesired images caused by the prior digital-to-analog conversion. Amplifiers 234a and 234b (Amp) amplify the signals from lowpass filters 232a and 232b, respectively, and provide in-phase (I) and quadrature (Q) baseband signals. Upconverters 240 include an in-phase upconverter 241a and a quadrature upconverter 241b that upconverter the in-phase (I) and quadrature (Q) baseband signals with in-phase (I) and quadrature (Q) transmit (TX) local oscillator (LO) signals from a TX LO signal generator 290 to provide upconverted signals. A filter 242 filters the upconverted signals to reduce undesired images caused by the frequency upconversion as well as interference in a receive frequency band. A power amplifier (PA) 244 amplifies the signal from filter 242 to obtain the desired output power level and provides a transmit radio frequency signal. The transmit radio frequency signal is routed through a duplexer/switch 246 and transmitted via an antenna 248.

In a receive path, the antenna 248 receives communication signals and provides a received radio frequency (RF) signal, which is routed through the duplexer/switch 246 and provided to a low noise amplifier (LNA) 252. The duplexer/switch 246 is designed to operate with a specific receive (RX) to transmit (TX) (RX-to-TX) duplexer frequency separation, such that RX signals are isolated from TX signals. The received RF signal is amplified by the LNA 252 and filtered by a filter 254 to obtain a desired RF input signal. Downconversion mixers 261a and 261b mix the output of the filter 254 with in-phase (I) and quadrature (Q) receive (RX) LO signals (i.e., LO_I and LO_Q) from an RX LO signal generator 280 to generate in-phase (I) and quadrature (Q) baseband signals. The in-phase (I) and quadrature (Q) baseband signals are amplified by amplifiers 262a and 262b and further filtered by lowpass filters 264a and 264b to obtain in-phase (I) and quadrature (Q) analog input signals, which are provided to the data processor 210. In the exemplary configuration shown, the data processor 210 includes analog-to-digital-converters (ADCs) 216a and 216b for converting the analog input signals into digital signals for further processing by the data processor 210.

In FIG. 2, the transmit local oscillator (TX LO) signal generator 290 generates the in-phase (I) and quadrature (Q) TX LO signals used for frequency upconversion, while a receive local oscillator (RX LO) signal generator 280 generates the in-phase (I) and quadrature (Q) RX LO signals used for frequency downconversion. Each LO signal is a periodic signal with a particular fundamental frequency. A phase locked loop (PLL) 292 receives timing information from the data processor 210 and generates a control signal used to adjust the frequency and/or phase of the TX LO signals from the TX LO signal generator 290. Similarly, a PLL 282 receives timing information from the data processor 210 and generates a control signal used to adjust the frequency and/or phase of the RX LO signals from the RX LO signal generator 280.

The wireless device 200 may support carrier aggregation and may (i) receive multiple downlink signals transmitted by one or more cells on multiple downlink carriers at different frequencies and/or (ii) transmit multiple uplink signals to one or more cells on multiple uplink carriers. For intra-band carrier aggregation, the transmissions are sent on different carriers in the same band. For inter-band carrier aggregation, the transmissions are sent on multiple carriers in different bands. Those skilled in the art will understand, however, that aspects described herein may be implemented in systems, devices, and/or architectures that do not support carrier aggregation.

The mobile RF transceiver 220 may be implemented in a small form factor and at a reduced cost for supporting a fifth-generation (5G) communications system application. In particular, the power amplifier (PA) 244 of the mobile RF transceiver 220 may be implemented as a digital power amplifier for supporting 5G communications. A switched-capacitor (SC) power amplifier (SCPA) is a type of digital power amplifier that possesses advantages over conventional power amplifiers. Advantages of SCPA digital power amplifiers include highly linear amplitude modulation (AM) and improved efficiency relative to conventional power amplifiers. The improved efficiency of SCPA digital power amplifiers is achieved by operating at a back-off power level from a saturated power level used to operate conventional power amplifiers at a high output power level. This feature of SCPA digital power amplifiers makes them an attractive candidate for 5G communications systems.

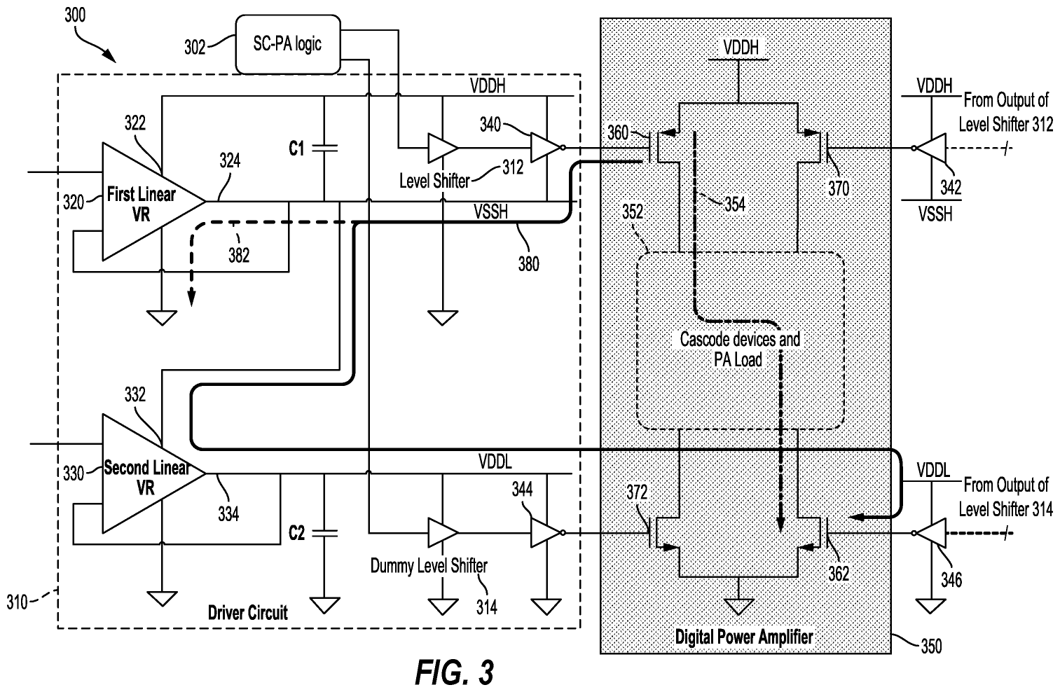

An SCPA digital power amplifier may be implemented using an inverter/buffer type of driver from a power amplifier supply. If the power amplifier is configured to generate high output power, the power amplifier devices are large and a driver current will impact the overall power amplifier driver and efficiency. The SCPA digital power amplifier may specify a pair of n-type metal oxide semiconductor (NMOS) and p-type metal oxide semiconductor (PMOS) switching devices, which may double the driver current when implemented as double-oxide devices. The proposed architecture addresses these issues by using single-oxide devices in at least a driver stage of a digital power amplifier. Using single-oxide devices in the digital power amplifier may achieve higher power amplifier efficiency while using less driver current. An efficient driver for a radio frequency (RF) switched-capacitor power amplifier (SCPA) is desirable for achieving a high output power as well as improved efficiency, for example, as shown in FIG. 3.

FIG. 3 is a schematic diagram illustrating an RF front-end (RFFE) module, including a driver circuit for a digital power amplifier configured to share charge, according to aspects of the present disclosure. In the configuration shown in FIG. 3, an RFFE module 300 includes a driver circuit 310 and a digital power amplifier 350 that are configured to support charge sharing between switching devices of the digital power amplifier 350. In contrast to conventional power amplifiers, using the driver circuit 310 for supporting charge sharing within the digital power amplifier 350 enables low power operation of the RFFE module 300 for supporting, for example, 5G communications systems.

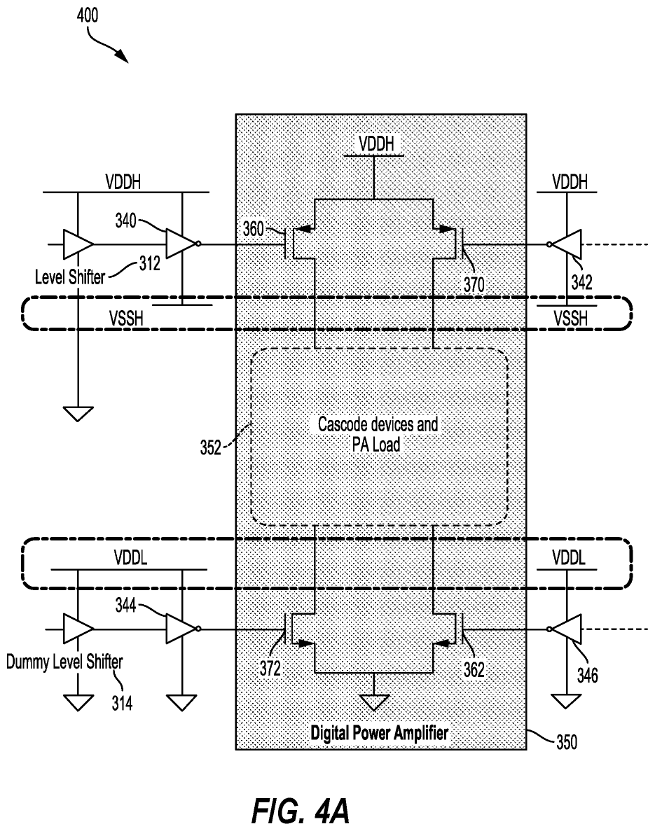

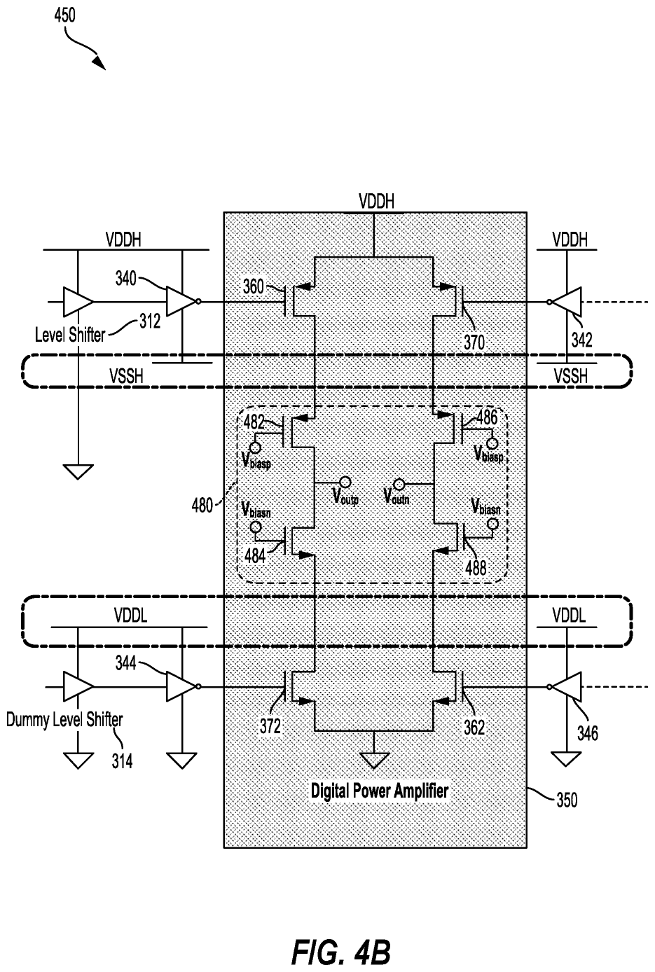

In the configuration shown in FIG. 3, the digital power amplifier 350 includes a first p-type metal oxide semiconductor (PMOS) switching device 360 and a first n-type metal oxide semiconductor (NMOS) switching device 362. The digital power amplifier 350 also includes a second PMOS switching device 370 and a second NMOS switching device 372. Cascode devices 352 are coupled between the switching devices (e.g., 360, 362, 370, 372) of the digital power amplifier 350. Further details of the cascode devices 352 are shown in FIG. 4B, according to one aspect of the present disclosure.

In this aspect of the present disclosure, an oxide thickness of the gate oxide of the switching devices (e.g., 360, 362, 370, 372) of the digital power amplifier 350 is configured using a single gate oxide thickness. By contract, the cascode devices 352 are configured using a double gate oxide thickness greater than (e.g., twice) the single gate oxide thickness of the switching devices (e.g., 360, 362, 370, 372) for avoiding breakdown when supporting a high output power level. Conventionally, supporting a high output power level involves implementing the switching devices as well as the cascode devices of conventional power amplifiers using double-oxide (DO) devices (e.g., a double-gate oxide thickness).

While using double-oxide devices enables support for high power level operation, double-oxide devices are inherently much slower than single-oxide devices. Furthermore, using double-oxide devices in a power amplifier lowers the power amplifier's efficiency because double-oxide devices are more resistive than single-oxide (SO) devices. Unfortunately, using double-oxide devices significantly increases a load capacitance of conventional power amplifiers. In addition, double-oxide devices also significantly increase a voltage across the driver of conventional power amplifiers, which also consumes significant driver current.

In aspects of the present disclosure, the driver circuit 310 for the digital power amplifier 350 is composed of single-oxide devices to enable charge sharing between the single-oxide switching devices (e.g., 360, 362, 370, 372) of the digital power amplifier 350. In this configuration, the driver circuit 310 includes a driver network configured to protect the single-oxide devices in the driver circuit 310 from breakdown. Representatively, the driver circuit 310 includes a first linear voltage regulator 320 having an output 324 coupled to a power supply input 332 of a second linear voltage regulator 330. A capacitor C1 is coupled between a power supply input 322 and the output 324 of the first linear voltage regulator 320. In addition, a capacitor C2 is coupled to an output 334 of the second linear voltage regulator 330. Each of the first linear voltage regulator 320 and the second linear voltage regulator 330 is coupled to the digital power amplifier 350 in a stacked configuration shown in FIG. 3.

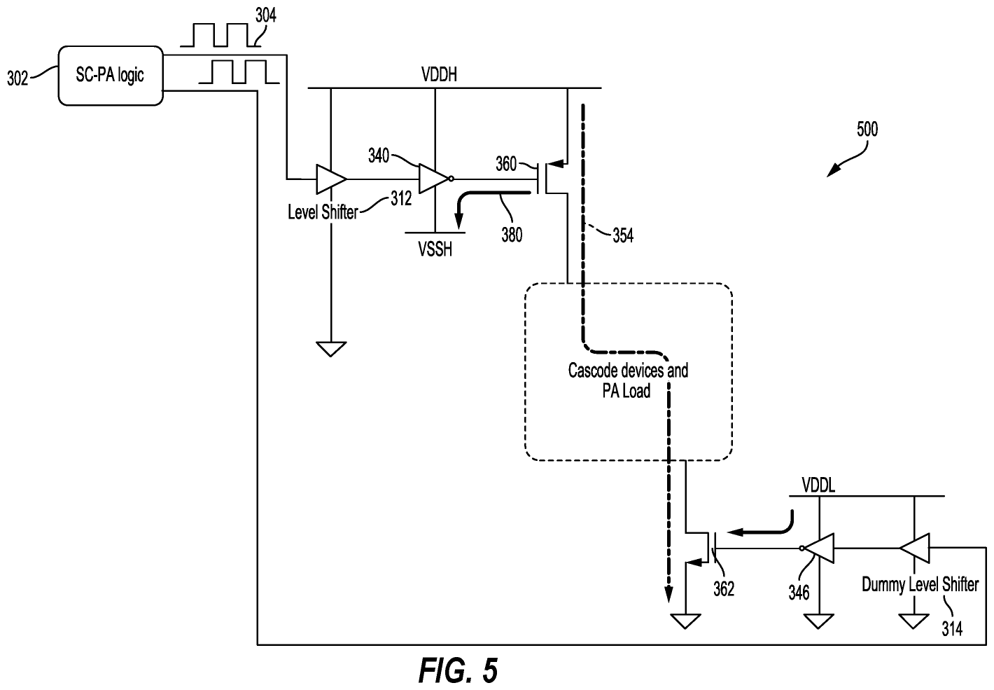

The driver network includes a level shifter 312 coupled to the first PMOS switching device 360 through a first inverter 340. The level shifter 312 is also coupled to the second PMOS switching device 370 through a second inverter 342. In addition, a dummy level shifter 314 is coupled to the first NMOS switching device 362 through a third inverter 346 and the second NMOS switching device 372 through a fourth inverter 344. In this configuration, the driver circuit 310 is configured to share charge between a gate of the first PMOS switching device 360 and a gate of the first NMOS switching device 362. The driver circuit 310 is also configured to share charge between a gate of the second PMOS switching device 370 and a gate of the second NMOS switching device 372 through the driver circuit 310. A power amplifier logic block 302 of the driver circuit 310 is described with respect to FIG. 5.

In operation, the driver network of the driver circuit 310 is configured to receive a first data signal having a first voltage range and to convert the first data signal to a second data signal having a second voltage range larger than the first voltage range, for example, as shown in FIGS. 4A, 4B, and 5.

FIG. 4A is a schematic diagram 400 illustrating a portion of the RFFE module 300 of FIG. 3, for enabling charge sharing through a driver circuit for a digital power amplifier, according to aspects of the present disclosure. In the configuration shown in FIG. 4A, a power amplifier supply voltage (VDDH) provides a power rail for the level shifter 312, the first PMOS switching device 360, the first inverter 340, and the second inverter 342. The first inverter 340 and the second inverter 342 also receive a level-shifted voltage (VSSH). In contrast, a driver supply voltage (VDDL) provides a power rail for the dummy level shifter 314, the third inverter 346, and the fourth inverter 344.

In one example configuration, the power amplifier supply voltage VDDH is set at three volts (3V). Unfortunately, the single-oxide devices may only tolerate a limited voltage before breakdown. To protect the single-oxide devices, the level-shifted voltage VSSH is set as follows:

VSSH=VDDH−VDDL (1)

In this aspect of the present disclosure, the level shifter 312 is configured to provide the level-shifted voltage VSSH to protect the first PMOS switching device 360 and the second PMOS switching device 370. For example, according to Equation (1), the level-shifted voltage VSSH is approximately 2.2 volts, assuming a 3.0 volt power amplifier supply voltage VDDH and a 0.8 volt driver supply voltage VDDL. By setting the level-shifted supply voltage VSSH according to Equation (1), it is possible to use single-oxide devices in the driver circuit 310 as well as the switching devices (e.g., 360, 362, 370, 372) of the digital power amplifier 350. By contrast, in conventional driver circuit configurations, current consumption is doubled by having by the first linear voltage regulator 320 and the second linear voltage regulator 330 independently supply the level-shifted voltage VSSH and the driver supply voltage VDDL.

FIG. 4B is a schematic diagram 450 illustrating a portion of the RFFE module 300 of FIG. 3, including cascode devices 480 of the digital power amplifier 350, according to aspects of the present disclosure. The portion of the RFFE module 300 of FIG. 3 shown in the schematic diagram 450 includes similar reference numbers to the schematic diagram 400 shown in FIG. 4A. In the configuration shown in FIG. 4B, the digital power amplifier 350 includes a first p-type metal oxide semiconductor (PMOS) cascode device 482 and a first n-type metal oxide semiconductor (NMOS) cascode device 484. The digital power amplifier 350 also includes a second PMOS cascode device 486 and a second NMOS cascode device 488. The cascode devices 480 are coupled between the switching devices (e.g., 360, 362, 370, 372) of the digital power amplifier 350.

In the configuration shown in FIG. 4B, the cascode devices 480 of the digital power amplifier 350 provide a differential output (Vₒᵤₜₚ, Vₒᵤₜₙ). In this configuration, the first PMOS cascode device 482 and the second PMOS cascode device 486 are each fed a first gate bias voltage (V_{biasp}). In addition, the first NMOS cascode device 484 and the second NMOS cascode device 488 are each fed a second gate bias voltage (V_{biasn}). In operation, the first PMOS cascode device 482 and the first NMOS cascode device 484 produce a positive differential output (Vₒᵤₜₚ). In this differential configuration, the second PMOS cascode device 486 and the second NMOS cascode device 488 produce a negative differential output (Vₒᵤₜₙ). In this configuration, the cascode devices 480 of the digital power amplifier 350 are implemented as double gate oxide devices.

Referring again to FIG. 3, the first linear voltage regulator 320 and the second linear voltage regulator 330 are shown in a stacked configuration, in which an output 324 of the first linear voltage regulator 320 is coupled to the power supply input 332 of the second linear voltage regulator 330. Stacking of the first linear voltage regulator 320 and of the second linear voltage regulator 330 enables charge sharing between the gates of the switching devices (e.g., 360, 362, 370, 372) of the digital power amplifier 350 using a driver current 380. A power amplifier current 354 is also shown in the digital power amplifier 350. In addition, an excess charge 382 of the driver current 380 is discharged to a ground rail through the first linear voltage regulator 320. Charge sharing through the driver circuit 310 between the switching devices (e.g., 360, 362, 370, 372) of the digital power amplifier 350, is further illustrated in FIG. 5.

FIG. 5 is a schematic diagram 500 illustrating a portion of the RFFE module 300 of FIG. 3, for configuring charge sharing through a driver circuit for a digital power amplifier, according to aspects of the present disclosure. In this configuration, the first PMOS switching device 360 is activated by discharging a gate of the first PMOS switching device 360. Activating the first PMOS switching device 360 causes the power amplifier current 354 to flow to the first NMOS switching device 362. The driver current 380 dumped away from the first PMOS switching device 360 during one RF cycle activates the first NMOS switching device 362 by charging a gate of the first NMOS switching device 362.

FIG. 5 further illustrates a power amplifier logic block 302 configured to initialize the first linear voltage regulator 320 and the second linear voltage regulator 330 of the driver circuit 310 for enabling effective charge sharing within the digital power amplifier 350 (shown in FIG. 3). In particular, the power amplifier logic block 302 is configured to generate an activation sequence signal 304. In the stacked configuration of FIG. 3, the second linear voltage regulator 330 is enabled and allowed to settle prior to enabling the first linear voltage regulator 320. Enabling the second linear voltage regulator 330 first ensures that the driver supply voltage VDDL does not exceed an operational limit (e.g., 0.8 volts) for protecting the single-oxide devices of the driver circuit 310 and the switching devices of the digital power amplifier 350.

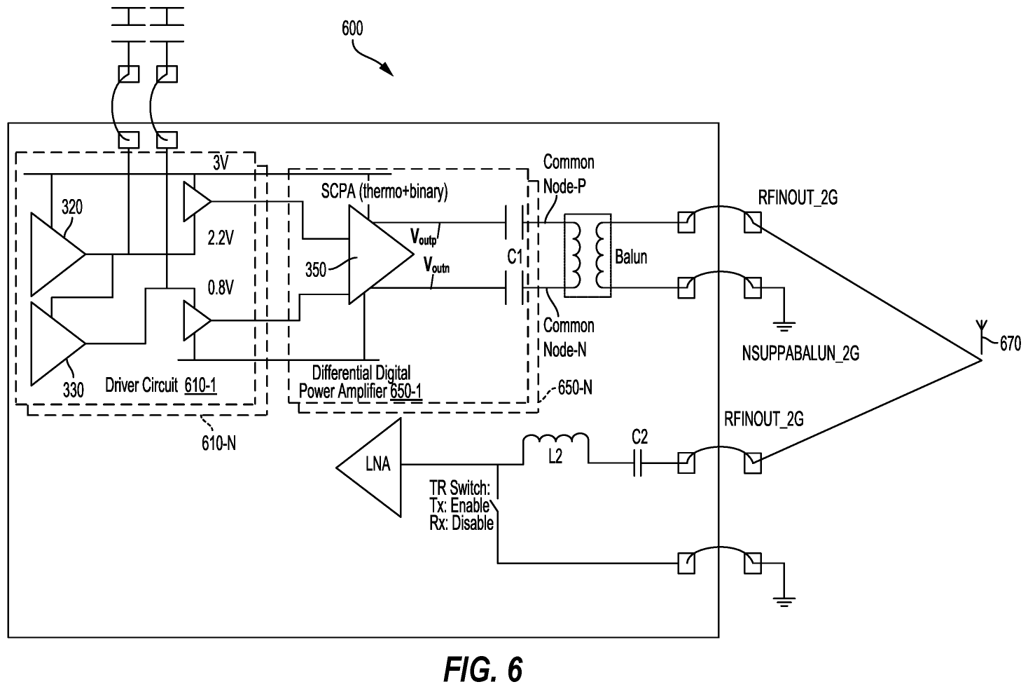

In this configuration, a size of the first PMOS switching device 360 and the second PMOS switching device 370 exceeds a size of the first NMOS switching device 362 and the second NMOS switching device 372. The larger size of the first PMOS switching device 360 and the second PMOS switching device 370 ensures there is sufficient charge for charging the first NMOS switching device 362 and the second NMOS switching device 372. Implementing the first PMOS switching device 360 and the second PMOS switching device 370 with the larger size is possible as PMOS mobility is usually lower relative to NMOS mobility, so PMOS devices are usually wider relative to NMOS devices. A differential configuration of an RF front-end module including an efficient driver for a digital power amplifier is shown in FIG. 6.

FIG. 6 is a schematic diagram illustrating an RF front-end (RFFE) module 600, including an efficient driver for a high power radio frequency (RF) digital power amplifier, according to aspects of the present disclosure. In this configuration, a differential digital power amplifier 650 (650-1, . . . , 650-N) is implemented as a switched-capacitor power amplifier (SCPA), although other digital power amplifier configurations are contemplated. The RFFE module 600 is shown using similar components and similar reference numerals to the RFFE module 300 shown in FIG. 3. Representatively, the digital power amplifier 350 of FIG. 3 is shown in a differential configuration of the differential digital power amplifier 650. By contrast, conventional power amplifiers use a single-ended power amplifier configuration. Unfortunately, single-ended power amplifier configurations exhibit a limited maximum output power.

In this example, the RFFE module 600 includes a single-ended antenna 670. As a result, a balun is coupled to differential outputs of the digital power amplifier 350 through capacitors C1 for converting a differential output signal (Vₒᵤₜₚ, Vₒᵤₜₙ) to a single-ended output signal for transmitting with the single-ended antenna 670. The balun is coupled to the differential digital power amplifier 650 through a common differential connection. The common differential connection comprises a common node-P and a common node-N corresponding to the differential output signals (Vₒᵤₜₚ, Vₒᵤₜₙ). It should be recognized that a single digital power amplifier (e.g., 350) and a single driver circuit 610 (610-1, . . . , 610-N) are shown to avoid obscuring details of the present disclosure. In particular, additional digital power amplifiers (e.g., 650-N) and additional driver circuits (e.g., 610-N) may be provided in a differential configuration, with their differential outputs (e.g., Vₒᵤₜₚ, Vₒᵤₜₙ) coupled to, respectively, the common node-P and the common node-N for each bit slice.

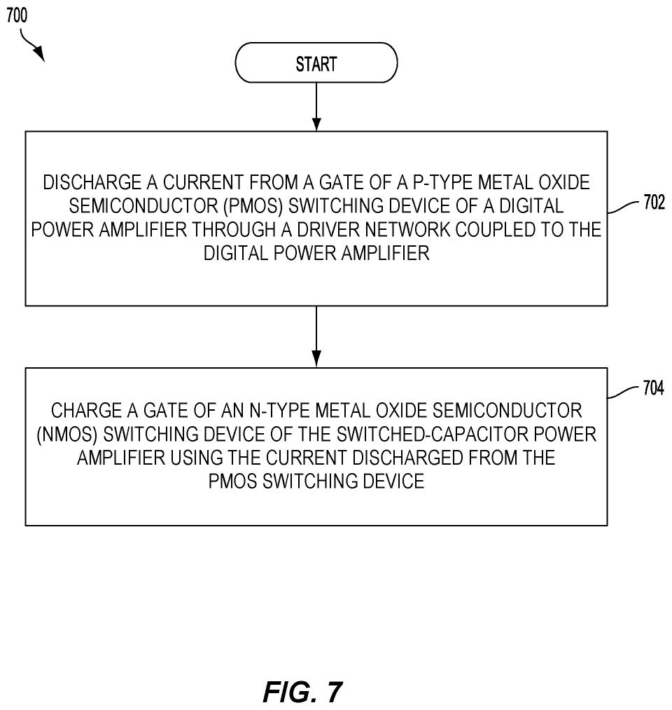

The RFFE module 600 also includes an integrated transmit/receive switch (TR). The integrated transmit/receive switch TR is coupled to an inductor L2, capacitor C2, and a low noise amplifier (LNA). When transmitting data, the integrated transmit/receive switch TR is on. When receiving data, the integrated transmit/receive switch TR is off. Including the integrated transmit/receive switch TR on-chip avoids an external switch, which would increase the size of the RFFE module 600. As a result, a form factor of the RFFE module 600 is reduced by the integrated transmit/receive switch TR for supporting 5G applications. A method of charge sharing in a digital power amplifier 350 is shown in FIG. 7.

FIG. 7 is a flow diagram illustrating a method 700 of sharing charge in a signal processing circuit, in accordance with aspects of the present disclosure. The blocks of the method 700 can be performed in or out of the order shown, and in some aspects, can be performed at least in part in parallel.

At block 702, a current from a gate of a p-type metal oxide semiconductor (PMOS) switching device of a digital power amplifier is discharged through a driver network coupled to the digital power amplifier. For example, as shown in FIG. 3, the driver current 380 is discharged from the first PMOS switching device 360 of the digital power amplifier 350. At block 704, a gate of an n-type metal oxide semiconductor (NMOS) switching device of the digital power amplifier is charged using the current discharged from the PMOS switching device. For example, as shown in FIG. 3, the driver current 380 is discharged from the gate of the first PMOS switching device 360 to charge the gate of the first NMOS switching device 362 of the digital power amplifier 350. This charge sharing process is also performed from the second PMOS switching device 370 to charge the second NMOS switching device 372.

Conventional power amplifiers generally operate at a saturated power level for supporting a high output power level, which results in less efficient operation. In addition, supporting a high output power level often involves implementing these conventional power amplifiers using double-oxide (DO) devices (e.g., a double-gate oxide thickness). Aspects of the present disclosure include a driver network coupled to a power amplifier of a signal processing device. In this aspect of the present disclosure, current from a PMOS switching device of a switched-capacitor power amplifier is discharged through the driver network coupled to the switched-capacitor power amplifier. In addition, an NMOS switching device of the switched-capacitor power amplifier is charged using the current discharged from the PMOS switching device. This charge sharing using the driver network between the PMOS and NMOS switching devices of the signal processing device reduces driver current consumption.

According to a further aspect of the present disclosure, a signal processing circuit includes a differential, digital power amplifier configured to share charge. The differential digital power amplifier includes at least a p-type metal oxide semiconductor (PMOS) switching device and an n-type metal oxide semiconductor (NMOS) switching device. The signal processing device also includes means for sharing charge between the PMOS switching device and the NMOS switching device. The means for sharing charge may, for example, include the driver circuit 310, including the driver network, as shown in FIGS. 3 to 6. In another aspect, the aforementioned means may be any module, or any apparatus configured to perform the functions recited by the aforementioned means.

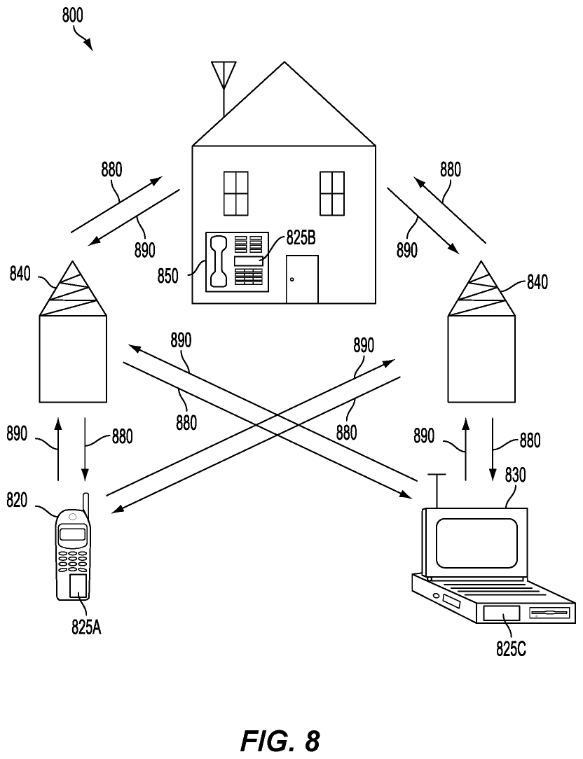

FIG. 8 is a block diagram showing an exemplary wireless communications system 800 in which an aspect of the present disclosure may be advantageously employed. For purposes of illustration, FIG. 8 shows three remote units 820, 830, and 850 and two base stations 840. It will be recognized that wireless communications systems may have many more remote units and base stations. Remote units 820, 830, and 850 include IC devices 825A, 825C, and 825B that include the disclosed differential, digital RF power amplifier. It will be recognized that other devices may also include the disclosed differential, digital RF power amplifier, such as the base stations, user equipment, and network equipment. FIG. 8 shows forward link signals 880 from the base station 840 to the remote units 820, 830, and 850 and reverse link signals 890 from the remote units 820, 830, and 850 to base station 840.

In FIG. 8, remote unit 820 is shown as a mobile telephone, remote unit 830 is shown as a portable computer, and remote unit 850 is shown as a fixed location remote unit in a wireless local loop system. For example, a remote units may be a mobile phone, a hand-held personal communications systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 8 illustrates remote units according to the aspects of the present disclosure, the present disclosure is not limited to these exemplary illustrated units. Aspects of the present disclosure may be suitably employed in many devices, which include the disclosed differential, digital RF power amplifier.

The accompanying claims and their equivalents are intended to cover such forms or modifications as would fall within the scope and spirit of the protection. For example, the example apparatuses, methods, and systems disclosed herein may be applied to multi-SIM wireless devices subscribing to multiple communications networks and/or communications technologies. The apparatuses, methods, and systems disclosed herein may also be implemented digitally and differentially, among others. The various components illustrated in the figures may be implemented as, for example, but not limited to, software and/or firmware on a processor, ASIC/FPGA/DSP, or dedicated hardware. In addition, the features and attributes of the specific example aspects disclosed above may be combined in different ways to form additional aspects, all of which fall within the scope of the present disclosure.

The foregoing method descriptions and the process flow diagrams are provided merely as illustrative examples and are not intended to require or imply that the operations of the method must be performed in the order presented. Certain of the operations may be performed in various orders. Words such as “thereafter,” “then,” “next,” etc., are not intended to limit the order of the operations; these words are simply used to guide the reader through the description of the methods.

The various illustrative logical blocks, modules, circuits, and operations described in connection with the aspects disclosed herein may be implemented as electronic hardware, computer software, or combinations of both. To clearly illustrate this interchangeability of hardware and software, various illustrative components, blocks, modules, circuits, and operations have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the various aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of receiver devices, e.g., a combination of a DSP and a microprocessor, a plurality of microprocessors, one or more microprocessors in conjunction with a DSP core, or any other such configuration. Alternatively, some operations or methods may be performed by circuitry that is specific to a given function.

In one or more exemplary aspects, the functions described may be implemented in hardware, software, firmware, or any combination thereof. If implemented in software, the functions may be stored as one or more instructions or code on a non-transitory computer-readable storage medium or non-transitory processor-readable storage medium. The operations of a method or algorithm disclosed herein may be embodied in processor-executable instructions that may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include random access memory (RAM), read-only memory (ROM), electrically erasable programmable read-only memory (EEPROM), FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

Although the present disclosure provides certain example aspects and applications, other aspects that are apparent to t hose of ordinary skill in the art, including aspects, which do not provide all of the features and advantages set forth herein, are also within the scope of this disclosure. For example, the apparatuses, methods, and systems described herein may be performed digitally and differentially, among others. Accordingly, the scope of the present disclosure is intended to be defined only by reference to the appended claims.

What is claimed is:

1. A signal processing circuit, comprising:
a power amplifier, comprising at least a p-type metal oxide semiconductor (PMOS) transistor and an n-type metal oxide semiconductor (NMOS) transistor; and
a driver circuit comprising a first linear voltage regulator having an output coupled to a power supply input of a second linear voltage regulator, the first linear voltage regulator and the second linear voltage regulator both coupled to the power amplifier.

2. The signal processing circuit of claim 1, in which the driver circuit is configured to conduct charge from a gate of the PMOS transistor to a gate of the NMOS transistor through the second linear voltage regulator.

3. The signal processing circuit of claim 2, in which the driver circuit comprises a level shifter coupled to the PMOS transistor and a dummy level shifter coupled to the NMOS transistor, in which the driver circuit is configured to receive a first data signal having a first voltage range and to convert the first data signal to a second data signal having a second voltage range larger than the first voltage range.

4. The signal processing circuit of claim 3, in which a gate of the PMOS transistor is coupled to the level shifter through a first inverter, and the NMOS transistor is coupled to the dummy level shifter through a second inverter.

5. The signal processing circuit of claim 1, in which the power amplifier comprises a digital power amplifier.

6. The signal processing circuit of claim 5, in which the digital power amplifier comprises a switched-capacitor power amplifier (SCPA).

7. The signal processing circuit of claim 1, in which the NMOS transistor and the PMOS transistor, each have a first gate oxide layer thickness.

8. The signal processing circuit of claim 7, in which the power amplifier comprises cascode transistors, each having a second gate oxide layer thickness greater than the first gate oxide layer thickness of the NMOS transistor and the PMOS transistor.

9. The signal processing circuit of claim 1, in which a gate of the PMOS transistor is coupled to the power supply input of the second linear voltage regulator through a first inverter, and a gate of the NMOS transistor is coupled to an output of the second linear voltage regulator.

10. The signal processing circuit of claim 1, further comprising power amplifier logic configured to activate the first linear voltage regulator and the second linear voltage regulator in an activation sequence.

11. A method of sharing charge in a signal processing circuit, comprising:
discharging a current from a gate of a p-type metal oxide semiconductor (PMOS) switching device of a digital power amplifier through a driver network coupled to the digital power amplifier; and
charging a gate of an n-type metal oxide semiconductor (NMOS) switching device of the digital power amplifier using the current discharged from the PMOS switching device.

12. The method of claim 11, in which discharging comprises level shifting a voltage at a gate of the PMOS switching device.

13. The method of claim 11, in which charging comprises converting a first data signal having a first voltage range at the gate of the PMOS switching device to a second data signal at the gate of the NMOS switching device having a second voltage range larger than the first voltage range.

14. The method of claim 11, further comprising activating a second linear voltage regulator prior to activating a first linear voltage regulator of a driver circuit of the signal processing circuit.

15. The method of claim 11, in which discharging comprises conducing the current from the gate of the PMOS switching device through a linear voltage regulator and an inverter to the gate of the NMOS switching device.

16. A signal processing circuit, comprising:
a differential digital power amplifier comprising at least a p-type metal oxide semiconductor (PMOS) transistor and an n-type metal oxide semiconductor (NMOS) transistor; and
means for conducting charge from a gate of the PMOS transistor through a linear voltage regulator to a gate of the NMOS transistor.

17. The signal processing circuit of claim 16, in which the NMOS transistor and the PMOS transistor are single oxide devices.

18. The signal processing circuit of claim 16, in which the differential digital power amplifier comprises a switched-capacitor power amplifier (SCPA).

19. The signal processing circuit of claim 16, in which the differential digital power amplifier comprises cascode devices configured as double oxide devices.

20. The signal processing circuit of claim 16, further comprising a first linear voltage regulator having an output coupled to a power supply input of a second linear voltage regulator, each coupled to the differential digital power amplifier.

21. The signal processing circuit of claim 20, further comprising power amplifier logic configured to activate the first linear voltage regulator and the second linear voltage regulator in an activation sequence.
